(19) United States
(12) Patent Application Publication
(10) Pub. No.: US 2004/0100282 A1
(43) Pub. Date: May 27, 2004

(54) Method and apparatus for determination of layer thickness in a multi-layer structure

(76) Inventors: Henrik Christensen, Birkerod (DK); Jorgen Nielsen, Allerod (DK); Liudas Mazeika, Kaunas (LT); Rymantas Kazys, Kaunas (LT)

Correspondence Address: HARNESS, DICKEY & PIERCE, P.L.C., P.O. BOX 8910, RESTON, VA, 20195, US

(21) Appl. No.: 10/658,774

(22) Filed: Sep. 10, 2003

Related U.S. Application Data
(60) Provisional application No. 60/409,596, filed on Sep. 11, 2002.

(30) Foreign Application Priority Data
Sep. 11, 2002 (DK) 2002 01336

(51) Int. Cl. G01R 27/04; G01R 27/32

(52) U.S. Cl. 324/644

(57) ABSTRACT

A method for determining thickness of a layer in a structure comprising at least one layer by means of, e.g., ultra sound measurements. Selects a first reflection from a response signal and uses this reflection as a basis for predicting the shape of a further reflection. The second reflection is subsequently located in the response signal by comparing the response signal to the predicted shape.

Provides a precise prediction of the shape of the further reflection, and thereby a precise measurement of the thickness.

The thickness of further layers may be determined.

May be used to determine the thickness of layers in a pipe during production of the pipe.

### FIELD OF THE INVENTION

The present invention relates to determination of thickness of a structure comprising at least one layer. In particular the invention relates to determination of the thickness of each layer in a multi-layer structure. Furthermore the invention relates to an apparatus for determining the thickness of a structure comprising at least one layer for example a multi-layer structure.

### BACKGROUND OF THE INVENTION

U.S. Pat. No. 6,250,159 describes a method for detection of thickness of layers in a multi-layer structure, such as layers on a substrate. The detection is based on an ultrasonic impulse measurement signal directed towards a structure under test. In an iterative process a received echo signal from the structure is subtracted by a calculated signal. The calculated signal is a sum of temporally shifted and weighted modifications of the impulse measurement signal. The iterative process is continued until a sum of squares of the subtraction is minimised. The measurement result is then found as the temporal shifts and weighting of the calculated signal.

### SUMMARY OF THE INVENTION

It is an object of the present invention to provide a method for determining thickness of at least one layer in a structure, the method being more precise than previously used methods.

According to a first aspect of the present invention, the above and other objects are obtained by providing a method for determining thickness of a layer in a structure comprising at least one layer, the method comprising the steps of:

providing a response signal representing a signal reflected by the structure,

selecting, from the response signal, a first reflection between a first layer and a previous layer,

predicting a shape of a further reflection from an interface between the first layer and a subsequent layer,

locating, in the response signal, the further reflection using the predicted shape of said second reflection,

determining a duration between the first reflection and the further reflection and, from the determined duration, determining the thickness of the first layer,

wherein the prediction is based upon the first reflection.

The structure may be a painted surface, on which the thickness of the layers of paint needs to be determined. The structure may be a composite material comprising a plurality of layers of materials. The structure may be a pipe comprising a plurality of layers. The structure may be a welding or layers of paper or fibreglass or a hull of a vessel or power cable. The method may be used in a portable device or in a processing machine. The method may be used during processing or production of a material or it may be used on a sample.

The determination of the thickness of a layer may be done on the basis of only one response signal such that each response signal (i.e. only one response signal) is used to obtain a measure for the thickness. The determination of the thickness may be done as an average of a plurality of response signals such as 2 or 3 or 4 or 5 or 6 or 7 or 8 or 9 or 10 or between 10 and 20. The average may be a cumulative average. In one embodiment a plurality of response signals may be divided into groups each comprising e.g. 10 response signals. For each group an average thickness may be determined.

It is a great advantage that the step of predicting a shape of a further reflection is based upon the first reflection because this provides a prediction which is more precise than a prediction based on a previously obtained reference measurement. Thus, the measurement used for the prediction is performed on the actual structure and under the actual circumstances. Furthermore, this feature provides the possibility of adjusting the predicted shape, e.g. by means of further reflections.

In an embodiment the method may comprise the step of transmitting a signal from a point of transmission towards the structure and receiving a reflected signal at a point of reception so as to provide the response signal. A transducer used to transmit and receive the signals and the reflections may be integrated in one unit but may also be provided in two different units. The signal may be transmitted with an angle of approximately 0 degrees in relation to a normal of the surface of the structure. In some embodiments the transmitted signal may be transmitted with an angle of 1 degree in relation to the normal or 2 degrees in relation to the normal or 3 degrees in relation to the normal or 4 degrees in relation to the normal or 5 degrees in relation to the normal or between 5 and 10 degrees in relation to the normal. The ultrasonic receiver may be provided with a similar angle as the transmitter but may also be provided with another angle.

The signal transmitted towards the structure may be an ultrasonic pulse, such as a pulse of white noise or pink noise or a pulse with Gaussian energy distribution. The pulse may be characterised by a centre frequency and a bandwidth. The centre frequency may be in the interval 1-15 MHz, such as in the interval 2-14 MHz, such as in the interval 3-13 MHz, such as in the interval 4-12 MHz, such as in the interval 5-11 MHz, such as in the interval 6-10 MHz, such as in the interval 7-9 MHz, such as in the interval 7.5-8.5. The bandwidth may be in the interval 0.25-10 MHz, such as in the interval 0.5-9 MHz, such as in the interval 1-8 MHz, such as in the interval 1.5-7 MHz, such as in the interval 2-6 MHz, such as in the interval 2.5-5 MHz, such as in the interval 3-4.5 MHz, such as in the interval 3.5-4 MHz. It should be understood that any combination of the above mentioned ranges can be used.

In an embodiment the centre frequency is approximately 5 MHz and the bandwidth is approximately 6 MHz.

In the step of determining the thickness of the layer it may be taken into account that the signal transmitted towards the substrate travels both forth and back and the different attenuation properties of the layers or media through which the signal travels may be taken into account.

The structure may be a multi-layer structure comprising at least two layers. In some embodiments the multi-layer structure may comprise 3 layers or 4 layers or 5 layers or 6 layers or 7 layers or 8 layers or 9 layers or 10 layers. The layers may comprise the same or different materials. If the structure comprises more than one layer, the thickness of the other layers may also be determined.

The method may further comprise the steps of:

from at least one of the first reflection or a second reflection, predicting a shape of a third reflection from an interface between a second layer and a subsequent layer,

locating, in the response signal, the third reflection using the predicted shape of said third reflection,

determining a duration between a previous reflection and the third reflection and, from the determined duration, determining the thickness of the second layer.

In some embodiments both the first and the second reflection may be used to predict the shape of the third reflection. In such a situation the first reflection may be used to predict the second reflection. The difference between the predicted and the actual second reflection may be used to improve the prediction of the third reflection.

In some embodiments the method may further comprise the steps of:

from at least one of the first, second or third reflection, predicting a shape of a fourth reflection from an interface between a third layer and a subsequent layer,

locating, in the response signal, the fourth reflection using the predicted shape of said fourth reflection,

determining a duration between a previous reflection and the fourth reflection and, from the determined duration, determining the thickness of the third layer.

In some embodiments the first, the second and the third reflection may be used to predict the shape of the fourth reflection. In such a situation the first and/or the second reflection may be used to predict the third reflection. The difference between the predicted and the actual third reflection may be used to improve the prediction of the fourth reflection.

The method according to the present invention may be adapted to measure thickness in a structure comprising more than three layers such as four or five or six or seven or eight or nine or ten.

The step of predicting the shape of the further reflection may comprise:

transforming the selected first reflection to a frequency domain,

applying an attenuation function to said transformed selected first reflection, so as to obtain a representation of the shape in the frequency domain,

transforming said representation to a time domain, so as to obtain the prediction of the shape.

The transformation of the selected first reflection from the time domain to the frequency domain may be performed using Fourier Transformation algorithms, such as Fast Fourier Transformation (FFT). The transformation of the representation of the predicted shape from the frequency domain to the time domain may be performed using algorithms for inverse Fourier Transformation, such as Inverse Fast Fourier Transformation (IFFT).

The first selected reflection corresponds spectrally to the wave transmitted into the first layer. The frequency dependent attenuation function characteristic of the material of the first layer may therefore be applied to the spectrum of the selected first reflection so as to obtain the spectrum of the predicted further reflection. The attenuation function may be estimated in a laboratory or provided from a table. By transforming the predicted spectrum to the time domain, the predicted shape of the further reflection is obtained.

Information about each of the at least one layer may be used in the prediction of the thickness. Thus, in some embodiments the thickness and/or attenuation properties of the layers of the substrate are used to determine the applied attenuation function. The substrate may comprise a plurality of layers, each of the layers may have different thickness and/or attenuation properties. This may be taken into account in the method. The propagation rate in one material may be different from that of another material. This may be taken into account when determining the thickness of the layers.

In the method the step of locating may comprise:

in the time domain, shifting the predicted shape between positions in an examination zone comprising at least a part of the response signal,

for each position, determining a degree of coincidence between the predicted shape and the response signal,

selecting the position having the best coincidence.

The predicted shape may be shifted along the entire response signal, or it may be shifted along a part of the response signal. In some embodiments the predicted signal is shifted in a predetermined window of the response signal. The predetermined window may be determined on the basis of a priori knowledge, such as an approximate thickness of one or more of the layers, or the speed of sound in the materials used in one or more of the layers.

The predicted shape may be shifted with predetermined step lengths or changing step lengths. The predetermined step length may be independent of the length of the window in which the predicted shape is shifted. E.g. the predicted shape may always be shifted in steps being between 0.01-5 μs, such as between 0.2-4 μs, such as 0.3-3 μs, such as 0.6-2 μs, such as 0.08-1 μs. The steps may also be determined as a fraction of the length of the window.

The determination of the degree of coincidence may be based on a calculated difference between the predicted shape and the response signal. This may be done by determining an area between the response signal and the predicted shape of the reflection. In one embodiment the coincidence may be determined by calculating a difference between the response signal and the predicted signal for a plurality of points in the signals, e.g. for each sample point.

The calculated difference may be determined on an L1 norm criterion. In the L1 norm criterion the absolute differences between corresponding sample value in the two signals are summarised. The calculated difference may be determined on a least square criterion.

In the least square criterion the squared differences between corresponding sample values of the two signals are summarised, thus differences between the response signal and the predicted shape are enhanced. Further criterions may summarise the differences raised to the third power or fourth power or fifth power etc. The information about the signal transmitted through the materials and attenuation properties of said materials may be used to predict the examination zone.

In one embodiment liquid may be provided between the point of transmission and the structure. This may be done as the signal will travel faster in liquid than in air. In one embodiment the liquid may comprise water, such as distilled water, such as salt water. In other embodiments the liquid may be oil such as mineral oil and/or vegetable oil and/or animal oil.

The structure may be or comprise a pipe. The pipe may comprise a plurality of layers, such as two layers or three layers or four layers or five layers or six layers or seven layers or eight layers or nine layers or ten layers. The layers may be made of the same material or they may be made of different materials. The layers may have different properties in relation to reflection and/or transmission and/or absorption.

The layers may be made of metal or plastic or glass or fibre materials or composites or any combination hereof. In one embodiment the pipe may be made of three layers where the middle layer is a metal layer and the outer and the inner layers are made of a plastic material. The pipe may be designed to be used in heating systems such as pipes to be used in under-floor heating.

The duration of the signal transmitted may be less than the time required for said signal to cover a first distance, said first distance extending from the point of transmission to an interface between two materials, at least one of said two materials being comprised in the structure. The interface may be the interface between the liquid and the first layer or the interface between the first and the second layer or the interface between the second and the third layer or the interface between the third layer and e.g. air. If the structure comprises more than three layers the interface may be any other interface in the structure.

The first distance may extend between the point of transmission and the first layer.

The signal transmitted from the point of transmission may be an ultrasonic signal. In some embodiments the signal may be a low frequency range signal or a mid frequency range signal or a high frequency range signal or a very high frequency range signal or a frequency in the audible range or a frequency in the infra red range or a frequency in UV range or an x-ray range.

In one embodiment an outer layer of the structure may comprise the first layer. The first layer may be comprised in the inner layer of the structure.

The present invention has the advantage of accurate measurement of individual layers in multilayer plastic pipes, some of which may possess very different acoustic properties, for example intermediate metallic layers. The method may be used for on-line control of manufacturing process of plastic pipes.

This method is based on filtering away the ultrasonic signals caused by multiple reflections in layers and leaving only the pulses caused by the first direct reflections at interfaces between adjacent layers. The thickness of each individual layer is found from the delay time between two neighbouring pulses left after the filtration procedure. For filtration procedure a priori knowledge about geometry of a pipe (number of layers, approximate thickness, type of materials, etc.) and acoustic properties of individual layers (ultrasound velocity, frequency dependent attenuation, etc.) is exploited.

An ultrasonic pulse is transmitted through a layer of water into a multilayer plastic pipe. Part of it is reflected by the external (front) surface of the pipe wall. The transmitted pulse propagates inside the pipe wall and is reflected back by interfaces between adjacent layers and the internal surface of the pipe wall. These reflected pulses are picked-up by an ultrasonic receiver, transformed into an electric signal, converted by analog-digital converter into a digital signal and stored in a computer. From this stored reflected signal the part corresponding to the signal reflected by the front surface of the pipe is selected.

The selected part is called the reference signal. This reference signal is used to find the new shape (waveform) of the ultrasonic pulse at the expected position of the interface between the first and the second layers, which is distorted by the frequency dependent attenuation of ultrasonic waves in the first layer.

The found distorted ultrasonic signal is subsequently shifted in the time domain until its position coincides with the position of the signal, reflected by the interface between the first and the second layer. Coincidence of these positions is determined according to the selected criterion, for example, the least square criterion. The thickness of the layer is found from the time interval between the positions of the pulses, reflected by the front surface of the pipe and by the interface between the first and second layer.

This procedure is repeated for the second layer, third layer, etc. After that the positions in the time domain of the ultrasonic pulses, the first time reflected by the interfaces between the first and second layers, the second and the third layers etc., are found. Thickness of the individual layers is found from the time interval between the positions of the neighbouring pulses. The total thickness of the multi-layer pipe is found as a sum of thickness of individual layers.

In one embodiment the present invention relates to a method of measuring thickness of individual layers in multi-layer plastic pipes, some of which are made of different materials, for example metal, said method comprising the steps of:

a) Transmitting an ultrasonic pulse into said structure through a layer of liquid, for example water, said ultrasonic pulse having a duration less than the time required for said pulse to propagate in a thickest layer;

b) Receiving echo pulses reflected by the front surface of the pipe and all interfaces between adjacent layers;

c) Storing the received waveforms of said reflected pulses;

d) Selecting, from the stored pulses, only the waveform corresponding to the front surface of the pipe;

e) Finding from the said selected pulse the new waveform of the ultrasonic pulse at the expected position of the interface between the first and the second layers, which is distorted by the frequency dependant attenuation of ultrasonic waves in the first layer;

f) Shifting in the time domain of the new waveform until its position coincides with the position of the ultrasonic signal reflected by the interface between the first and the second layer. Coincidence of these positions is determined according to the selected criterion. The shifting is performed with steps equal to a sampling period of the ultrasonic signal;

g) The thickness of the first layer is found from the time interval between the positions of the pulses, reflected by the front surface of the pipe and by the interface between the first and second layers;

h) Finding from the waveform, selected according to the step (d) and corresponding to the front surface of the pipe, the new waveform of the directly reflected ultrasonic pulse at the expected position of the interface between the second and the third layers, which is distorted by the frequency dependant attenuation of ultrasonic waves in the first and the second layers;

i) Finding from the waveform, selected according to the step (d) and corresponding to the front surface of the pipe, the new waveform of the multiple-reflected in the previous layers ultrasonic pulse at the expected position of the interface between the second and the third layers, which is distorted by the frequency dependent attenuation of ultrasonic waves in the first and the second layers;

j) In the case of the thin layers when the signals reflected by different interfaces can overlap, the direct reflection from the interface between the first and the second layers is included in the step (i);

k) Shifting in the time domain of the waveform determined in the step (h) and adding with waveform found in the step (i);

l) Repeating the step (k) with different shifts in the time domain until a best coincidence of the new waveform with the part of the signal, corresponding to the reflection from the interface between the second and the third layers will be reached. Coincidence of these positions is determined according to the selected criterion;

m) The thickness of the second layer is found from the time interval between the determined positions of the pulses, reflected by the interface between the first and second layer of the pipe and by the interface between the second and third layer;

n) The thickness of the next layer is found by repeating consequently the steps (h)-(m) for each next layer.

In the aforementioned embodiment the coincidence of the positions of the shifted reference signal and the signal, reflected by the interface between the chosen layers may be determined according to the L1 norm criterion.

In the aforementioned embodiment the coincidence of the positions of the shifted reference signal and the signal, reflected by the interface between the chosen layers may be determined according the least square criterion.

The first aspect of the invention may comprise any combination of elements or features of the second and/or third and/or fourth and/or fifth aspect of the invention.

According to a second aspect, the present invention provides an apparatus for determining thickness of a layer in a structure comprising at least one layer, the apparatus comprising:

means for transmitting a signal and means for detecting a response signal,

processing means adapted to process the response signal in accordance with the method of the first aspect of the invention.

The apparatus may be portable or stationary. The apparatus may comprise an ultrasonic transducer and/or an electric generator and/or an amplifier and/or a microprocesser and/or a memory. The apparatus may be adapted to be used in a production environment such that output of a production system may be constantly monitored.

The processing means may comprise a computer programme adapted to perform the method according to the first aspect of the invention.

The second aspect of the invention may comprise any combination of elements or features of the first and/or third and/or fourth and/or fifth aspect of the invention.

According to a third aspect, the present invention provides a computer system comprising data processing means which co-operates with computer program means to perform the method of the first aspect of the invention.

The computer programme may comprise a microprocessor and/or a memory and/or a data entering means and/or a screen. The computer system may be adapted to operate on a unix platform and/or a Linux platform and/or a dos platform and/or a windows platform.

The third aspect of the invention may comprise any combination of elements and/or features of the first and/or second and/or fourth and/or fifth aspect of the invention.

According to a fourth aspect, the present invention provides a computer programme for a computer system according to the third aspect of the invention.

The computer programme may be adapted to run on an internet and/or intranet. The computer programme may be adapted to operate on a unix platform and/or a Linux platform and/or a dos platform and/or a windows platform.

The fourth aspect of the invention may comprise any combination of elements or features of the first and/or second and/or third and/or fifth aspect of the invention.

According to a fifth aspect, the present invention relates to the use of the method according to the first aspect of the invention, wherein the method is used to determine thickness of layers in a pipe during production of said pipe.

The fifth aspect of the invention may comprise any combination of elements or features of the first and/or second and/or third and/or fourth aspect of the invention.

### BRIEF DESCRIPTION OF THE DRAWINGS

Preferred embodiments of the invention will be described in details below with reference to the accompanying FIGS. 1-7.

FIG. 1 shows an apparatus according to the present invention,

FIG. 2 shows an emission and a reflection of a signal,

FIG. 3 shows a recording of a response signal,

FIG. 4 shows a predicted shape of a reflection,

FIG. 5 shows shifting and comparing a predicted shape of a reflection in an examination interval of a response signal,

FIG. 6 shows the total signal loss versus frequency, and

FIG. 7 shows measurement errors for different methods of measurement.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

### DETAILED DESCRIPTION OF THE INVENTION

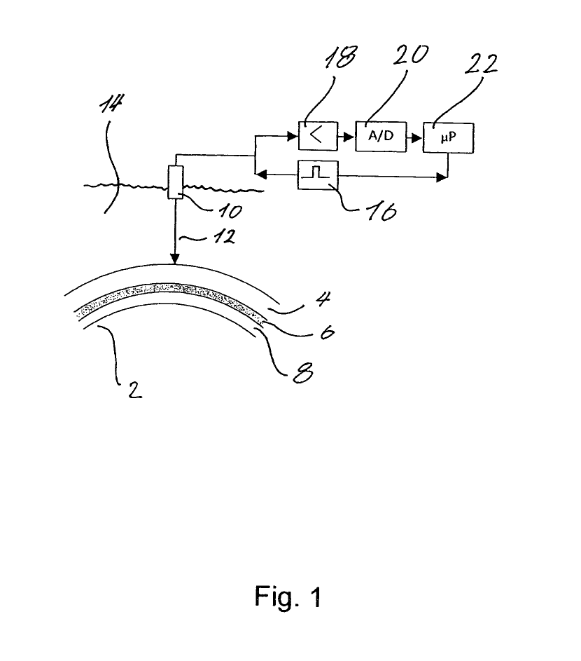

In FIG. 1 is shown a cross sectional view of a pipe 2 with a multi-layer structure, which in the embodiment of FIG. 1 comprises a first layer 4, a second layer 6 and a third layer 8. The first and the third layer may comprise a plastic material and the second layer may comprise a metallic material. In the embodiment shown in FIG. 1 an ultrasonic transducer 10 emits an ultrasonic signal 12 towards the pipe 2 and reflections from the layers of said pipe are picked up by the ultrasonic transducer 10. The ultrasonic signal has a duration which is at least shorter than the propagation time in a thickest layer of the pipe. The ultrasonic signal is transmitted into the pipe through a liquid 14. The ultrasonic transducer 10 is exited by an electric generator 16. The reflected signal is amplified by an amplifier 18, converted by an analogue-digital converter 20 and stored in the microprocessor 22.

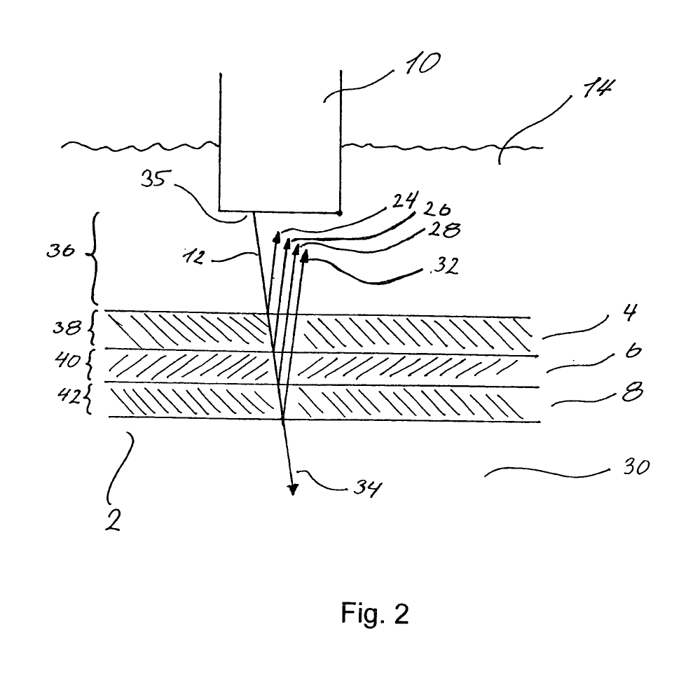

FIG. 2 additionally shows a cross sectional view of a pipe 2, which in the embodiment of FIG. 2 comprises a first 4, a second 6 and a third 8 layer. An ultrasonic transducer 10 emits an ultrasonic signal 12 towards the pipe 2. An interface between a liquid 14 and the first layer 4 of the pipe causes a first reflection 24. An interface between the first layer 4 and the second layer 6 causes a second reflection 26. An interface between the second layer 6 and the third layer 8 causes a third reflection 28. An interface between the third layer 8 and a subsequent layer 30 (e.g. water or air) causes a fourth reflection 32. A part 34 of the emitted signal 12 passes through the entire pipe. The first 24, second 26, third 28 and fourth 32 reflections are picked up by the ultrasonic transducer 10.

The duration of the emitted signal may be shorter than the time it takes said signal to travel a water distance 36 between a point of emission 35 and the interface between the liquid 14 and the first layer 4.

The duration of the emitted signal may be shorter than the time it takes said signal to travel a first layer distance 38, the first layer distance being the thickness of the first layer 4.

The duration of the emitted signal may be shorter than the time it takes said signal to travel a second layer distance 40, the second layer distance being the thickness of the second layer 6.

The duration of the emitted signal may be shorter than the time it takes said signal to travel a third layer distance 42, the third layer distance being the thickness of the third layer 8.

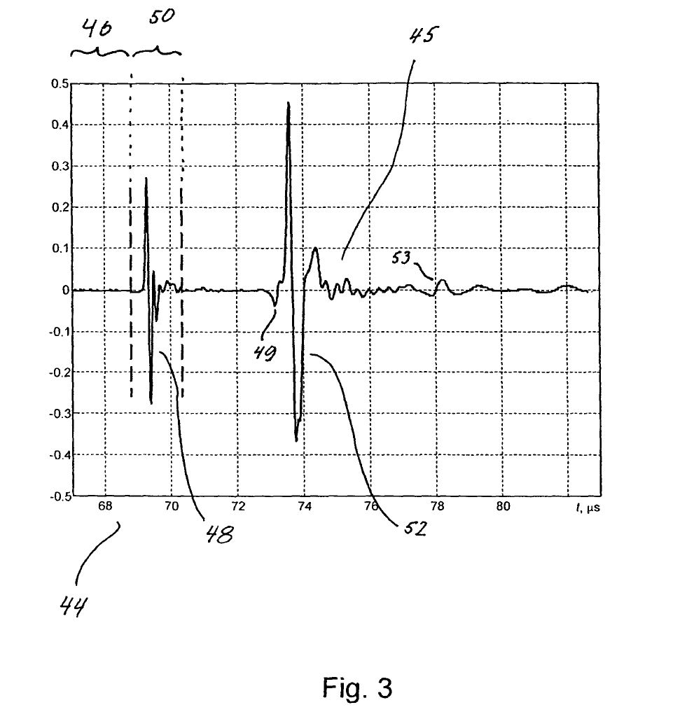

FIG. 3 shows a chart 44 comprising a response signal 45 from an ultrasonic signal transmitted from a point of transmission towards a structure, e.g. a pipe. From the time of transmission to the first reflection is received by the ultrasonic receiver a time period of approximately 69 μs elapses as indicated by the reference number 46. A first reflection 48 is then received, the first reflection 48 having a duration indicated by the reference number 50. After reception of the first reflection the ultrasonic receiver receives further reflections. E.g. a second reflection 52 is received. The time it takes to receive the reflections (e.g. the first reflection 48) represents the time it takes the ultrasonic waves to travel from the point of transmission through various layers and back again from an interface between two layers. E.g. the second reflection 52 travels through a liquid (e.g. water), penetrates the surface of the first layer of the structure and is reflected by an interface between the first and the second layer in the structure. Hereafter the wave travels back to the ultrasonic receiver, first through the first layer and then through the liquid. As illustrated in FIG. 3, the shape of the first reflection and further reflections, e.g. the second reflection, are not alike. Firstly the amplitudes are different, and secondly the actual shapes are different. The reason why the amplitude of the second reflection is higher than the first reflection may be that the interface between the liquid and the first layer has lower reflectory properties than the interface between the first and the second layer. FIG. 3 shows that the shape of the reflections are not alike and thus a standard shape for a reflection can not be used to detect a reflection—both the first refelction and subsequent reflection—as the shape of said reflection depends on the material properties relating to reflection, transmission and absorption of different wavelengths. The present invention uses the shape of the first reflection and information about the material(s) through which the ultrasonic wave is transmitted to predict the shape of further reflections.

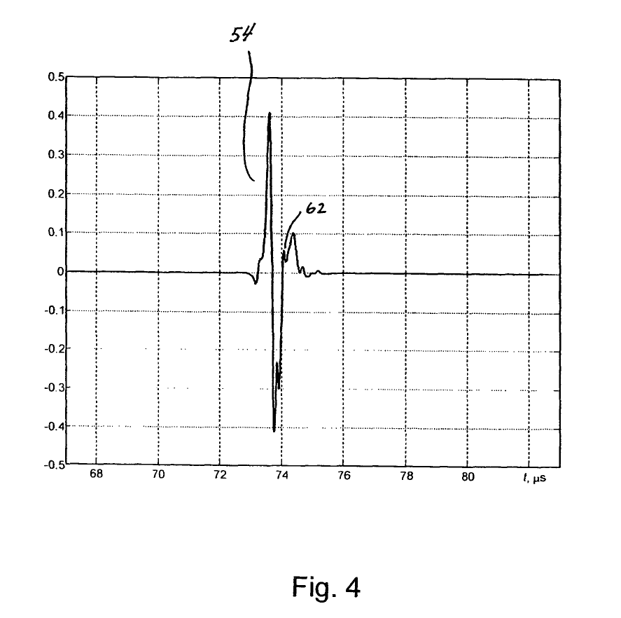

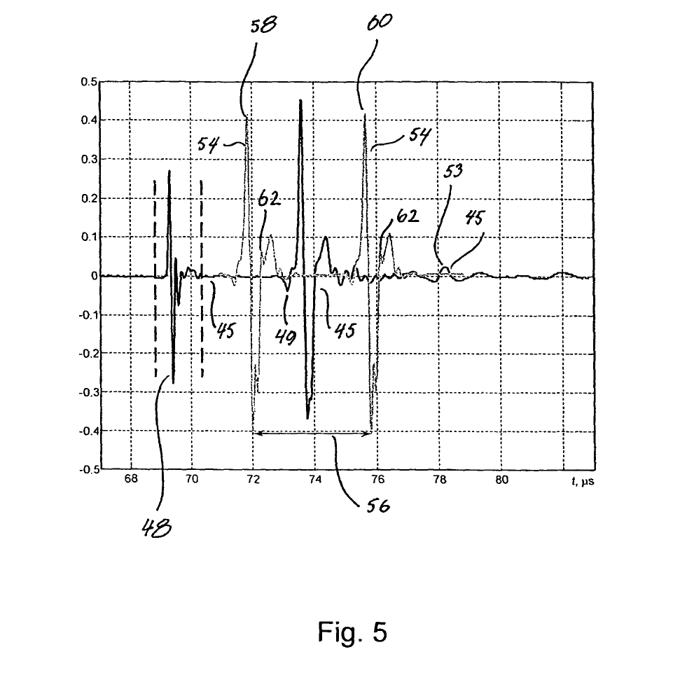

FIG. 4 shows a prediction 54 of the shape of the second reflection 52 in a response signal 45 shown in FIG. 3. As it may be seen the shape of the prediction 54 does not coincide with the first reflection 48 of the response signal 45. On the contrary, the shape of the prediction 54 coincides with the second reflection 52. The prediction 54 is obtained by, in the frequency domain, applying an attenuation function to the first reflection and then providing the predicted shape by transformation to the time domain. In the time domain the prediction 54 is shifted so as to detect coincidence with the response signal. The prediction is shifted in an examination interval 56 which is determined on basis of a priori knowledge of an approximate thickness of the structure and material properties. In FIG. 5 the reference numbers 58 and 60 represents examination of coincidence of the prediction 54 in the beginning and the end of the examination interval 56 respectively. For each position of the prediction a measure representing the deviation between the shapes of the prediction 54 and the response signal 45 is calculated, and a minimum of this measure in the examination interval is determined. Ideally the determined minimum measure should be zero but in reality a deviation between the predicted shape 54 and the actual shape of the second reflection 52 may occur. In FIG. 5 such a deviation may be detected visually as a small peak 62 in the prediction which is not present in the actual second reflection.

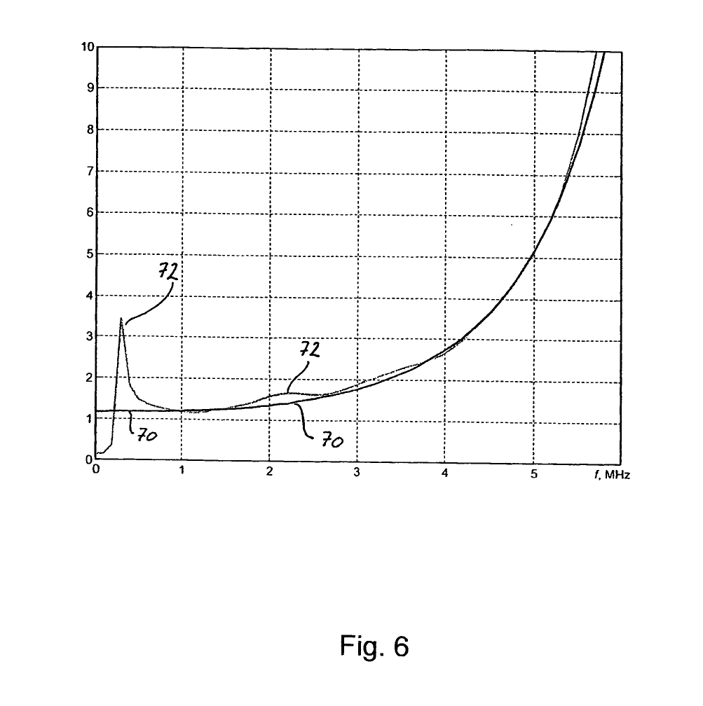

FIG. 6 shows a plot of an estimated 70 and a measured 72 frequency dependent attenuation function for a given material. The estimated attenuation function 70 can be written as hₐₜₜ(f)=K·exp(α·x·fⁿ), where K, α and n are characteristic coefficients for the material, f denotes frequency and x denotes position in the material. The coefficients can for any given material be estimated experimentally using e.g. Fast Fourier Transformation from an experimental attenuation curve. It appears from FIG. 6 that the estimated attenuation function 70 is very close to the measured attenuation function 72 for frequencies above 1 MHz.

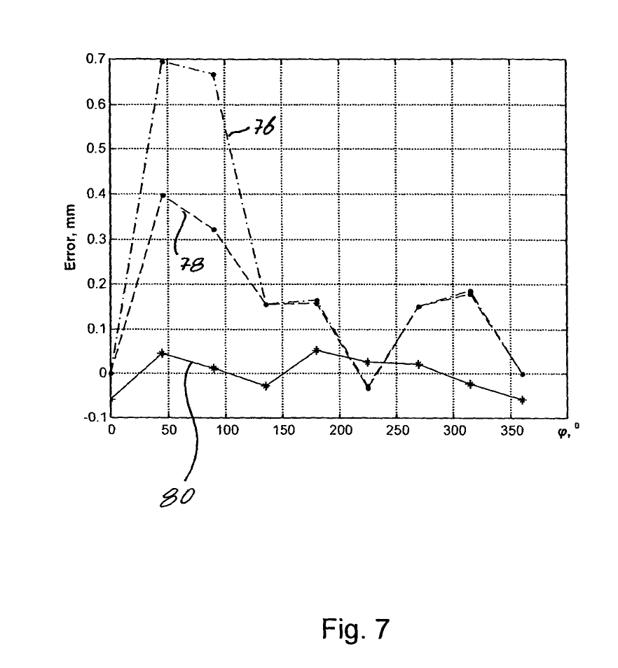

FIG. 7 presents a plot of measurement errors of the total wall thickness around a 4 layer pipe with intermediate aluminium layer obtained by 3 different methods: zero-crossing method 76, cross-correlation method 78 and the method proposed in this invention 80. Using the zero-crossing method the delay between the reference signal and the signal reflected by corresponding interface is found as the time difference between time instants when the both signals cross the zero level. In the case of the cross-correlation method the cross-correlation function between the reference signal and the reflected signal is calculated. The delay time corresponds to the position of the peak of cross-correlation function in the time domain. The results presented indicate that in the case of multi-layer plastic pipes with metallic intermediate layers the proposed method gives 10-20 times smaller measurement error than the known methods.

The method and apparatus enable to determine thickness of the individual layers and total thickness of multi-layer plastic pipe with intermediate one or few metallic layers during manufacturing process of the pipe with an enhanced accuracy having only one side approach to the pipe.

In the embodiment of FIG. 1 is shown a cross-sectional view of multi-layer plastic pipe 2 with one intermediate metallic layer and a block diagram showing one embodiment of measurement instrument. As shown in FIG. 1 the pipe 2 may consist of an external plastic layer 4, internal layer 8, which may be of different plastic material, and one or a few intermediate layers, one of which may be a metallic layer 6. Throughout production the thickness of individual layers and the total thickness must be controlled in order to assure quality of the pipe.

The present invention uses short ultrasonic pulses, duration of which is at least shorter than propagation time in a thickest layer of the pipe. Ultrasonic pulses 12 are radiated and picked up by ultrasonic transducer 10, which is excited by electric generator 16. These ultrasonic pulses are transmitted into the pipe through liquid 14, for example water, into which the pipe is submersed. These pulses are first of all reflected by an external surface of the pipe and then subsequently reflected by all interfaces between adjacent layers, possessing different acoustic impedances and the internal surface of the pipe wall. In the embodiment of FIG. 2 is shown reflected ultrasonic echo signals from the 4 layers pipe with an intermediate aluminium layer (plastic/very thin glue layer/aluminium/plastic). The pulse 52 is reflected by external surface of the pipe, the small pulse 49 is reflected by the thin glue layer. The pulse 52 is reflection from the aluminium layer including the interference of pulses a few times reflected inside this layer. The pulse 53 is the result of overlapped reflection from the inner surface of the pipe and the double reflection in the first plastic layer. The amplitudes and the waveforms of the reflected pulses depend on reflection coefficients at the interfaces and frequency dependent attenuation of ultrasonic waves in these layers. All these reflected pulses are picked-up by an ultrasonic receiver 10, transformed into an electric signal, amplified by the amplifier 18, converted by an analogue-digital converter 20 into a digital signal and stored in a computer 22. From this stored reflected signal the part corresponding to the signal reflected by the front surface of the pipe is selected. This part of the plot in the embodiment of FIG. 2 is denoted by a dashed line. The selected part is called the reference signal u_{ref}(t).

This reference signal is used to find the new shape (waveform) of the ultrasonic pulse at the expected position of the interface between the first and the second layers, which is distorted by the frequency dependent attenuation of ultrasonic waves in the first layer. The plastic layer may be presented as a filter with frequency dependent transfer function. The frequency dependent attenuation of ultrasonic waves in that layer must be measured by known methods in advance or taken from a literature. The attenuation function is defined as a filter with a frequency dependent attenuation hₐₜₜ(ƒ)=Ke^{αxƒ}_{ₙ}, where K, α, n are coefficients determining character of attenuation for each layer in a pipe. The values of the coefficients K, a, n must be estimated. For example, they can be estimated from the experimental attenuation curve

$${h}_{ex} ( f ) = \vert \frac{FT [ {u}_{ref} ( t ) ]}{FT [ {u}_{m} ( t ) ]} \vert ,$$

where uₘ(t) is the measured reflection from the analyzed interface, and FT denotes fast Fourier transform. The example of the measured and approximated attenuation function is presented in FIG. 6.

The waveform of the ultrasonic signal at the expected position of the interface is found from the convolution of the waveform of the reference signal at the input of the filter with the transfer function of the filter. Usually this convolution is performed in the frequency domain. For this purpose the Fourier transform of the reference signal is calculated and divided by the frequency dependent attenuation function of the first layer.

Then the shape of the attenuated ultrasonic signal is found as the inverse Fourier transform of the signal spectrum at the output of this filter:

$${u}_{att} ( t ) = {FT}^{- 1} [ \frac{FT ⌊ {u}_{ref} ( t ) ⌋}{{h}_{att} ( f )} ] ,$$

where FT¹ denotes inverse Fourier transform. In the case when a few reflected signals are very close to each other or they are overlapping, all of them are included in the simulated signal. An example of the ultrasonic signal, calculated in the described way, reflected by an intermediate aluminium layer, is shown in the embodiment of FIG. 4. Hence, in general the simulated signal at the expected position of the interface is found as a sum of the reflections, which falls into the analysed time window.

The found distorted ultrasonic pulse is subsequently shifted until its position coincides with the position of the measured reflection from the interface between the first and the second layer. The start and end positions of the scanning interval are defined by the

$${t}_{start} = \frac{2 {d}_{min}}{c} + {t}_{0} , {t}_{stop} = \frac{2 {d}_{max}}{c} + {t}_{0} ,$$

where dₘᵢₙ and dₘₐₓ are minimal and maximal possible values of the layer under investigation, t₀ is the delay time of the signal reflected from the tube external surface. The shift value, e.g. scanning step of the reference signal, is selected taking into account two contradicting requirements: the bigger the step, the faster the measurement process, however the lower accuracy of detection of the position of the interface. In general the uncertainty of measurement is defined as the Δt·c/2, where Δt is the shift step and c is the ultrasound velocity in a plastic material. In most cases shifting is performed with the step Δt equal to the sampling period of an ultrasonic signal.

In principle the shift step may be selected shorter than the sampling period, however in this case for coincidence estimation the interpolation procedures between sampling points is required.

The sampling frequency depends on a bandwidth of ultrasonic signal spectrum and according to the Nyquist criterion should be 2 times higher than the width of the band-limited signal spectrum. However, in order to reduce the measurement error due to sampling, the sampling frequency is selected approximately 10 times higher than the highest frequency component in the signal spectrum.

For example, in the case of the signals shown in the embodiment of FIG. 5 and which were reflected from the 4 layer pipe, the preferred frequency of ultrasonic signals is in the range 5-10 MHz. In order to get accuracy of measurement 10-20 μm the sampling frequency should be at least 100 MHz. Therefore, the reference signal during scanning process is shifted by 10 ns steps. In the scanning interval 56, shown in the embodiment of FIG. 5 between two extreme expected positions 58 and 60 (duration of the interval 3800 ns), there will be approximately 380 shifts performed. If thickness variations of the plastic layer are smaller, the scanning interval may be selected shorter and correspondingly the number of steps will be smaller. After these steps the position of the interface between the first and the second layer is found.

The coincidence of these positions is determined according to the selected criterion, for example, the L1 norm or the least square criterion. In the case of the L1 norm criterion after each shift step the absolute integral difference Kₒₚ is calculated

$${K}_{op} = {\int }_{{t}_{1}}^{{t}_{2}} \vert {u}_{m} ( t ) - {u}_{att} ( t ) \vert ⅆ t ,$$

where t₁ and t₂ are start and end instants of the time window in which the attenuated reference signal is located. The best coincidence between the attenuated reference signal and the ultrasonic signal reflected from the first interface is at the instant tₒₚ₁ at which Kₒₚ obtains a global minimum value.

The thickness of the first layer is found from the time interval between the positions of the pulses, reflected by the front surface of the pipe t_{f} and by the interface between the first and second layer tₒₚ₁:

$${l}_{1} = \frac{( {t}_{f} - {t}_{op1} ) {c}_{1}}{2} ,$$

where c₁ is the ultrasound velocity in the first plastic layer.

This procedure is repeated for the second layer, third layer, etc., however in this case the information about the thickness of previous layers is taken into account. That is, the multiple reflected pulses in the previous layers and distorted due to a frequency dependent attenuation are added to the shifted in the time domain reference signal, and only after that it is compared with the measured signal. The coincidence is found again changing the position of the reference signal in the time domain. After that the positions of the ultrasonic pulses in the time domain, the first time reflected by the interfaces between the first and second layers, the second and the third layers, etc., are found. Thickness of the individual layers is found from the time interval between the positions of the neighbouring pulses. The total thickness of multi-layer pipe is found as a sum of thickness of individual layers.

In the embodiment of FIG. 7 is presented measurement errors of the total wall thickness around the 4 layer pipe with intermediate aluminium layer obtained by 3 different methods: zero-crossing method 76, cross-correlation method 78 and the method proposed in this invention 80. Using the zero-crossing method the delay between the reference signal and the signal reflected by corresponding interface is found as the time difference between time instants when the both signals cross the zero level. In the case of the cross-correlation method the cross-correlation function between the reference signal and the reflected signal is calculated. The delay time corresponds to the position of the peak of cross-correlation function in the time domain. The results presented indicate that in the case of multi-layer plastic pipes with metallic intermediate layers the proposed method gives 10-20 times smaller measurement error than the known methods.

The method and apparatus enable to determine thickness of the individual layers and total thickness of multi-layer plastic pipe with intermediate one or few metallic layers during manufacturing process of the pipe with an enhanced accuracy having only one side approach to the pipe.

1. A method for determining thickness of a layer in a structure comprising at least one layer, the method comprising the steps of:
providing a response signal representing a signal reflected by the structure,
selecting, from the response signal, a first reflection between a first layer and a previous layer,
predicting a shape of a further reflection from an interface between the first layer and a subsequent layer,
locating, in the response signal, the further reflection using the predicted shape of said second reflection,
determining a duration between the first reflection and the further reflection and, from the determined duration, determining the thickness of the first layer,
wherein the prediction is based upon the first reflection.

2. A method according to claim 1, further comprising the step of:
transmitting a signal from a point of transmission towards the structure and receiving a reflected signal at a point of reception, so as to provide the response signal.

3. A method according to claim 1, wherein the structure is a multi-layer structure comprising at least two layers.

4. A method according to claim 1, further comprising the steps of:
from at least one of the first reflection or a second reflection, predicting a shape of a third reflection from an interface between a second layer and a subsequent layer,
locating, in the response signal, the third reflection using the predicted shape of said third reflection,
determining a duration between a previous reflection and the third reflection and, from the determined duration, determining the thickness of the second layer.

5. A method according to claim 1, further comprising the steps of:
from at least one of the first, second or third reflection, predicting a shape of a fourth reflection from an interface between a third layer and a subsequent layer,
locating, in the response signal, the fourth reflection using the predicted shape of said fourth reflection,
determining a duration between a previous reflection and the fourth reflection and, from the determined duration, determining the thickness of the third layer.

6. A method according to claim 1, wherein the step of predicting the shape of the further reflection comprises:
transforming the selected first reflection to a frequency domain,
applying an attenuation function to said transformed selected first reflection, so as to obtain a representation of the shape in the frequency domain,
transforming said representation to a time domain, so as to obtain the prediction of the shape.

7. A method according to claim 6, wherein thickness and attenuation properties of the layers of the substrate are used to determine the applied attenuation function.

8. A method according to claim 1, wherein the step of locating comprises:
in the time domain, shifting the predicted shape between positions in an examination zone comprising at least a part of the response signal,
for each position, determining a degree of coincidence between the predicted shape and the response signal,
selecting the position having the best coincidence.

9. A method according to claim 8, wherein determination of the degree of coincidence is based on a calculated difference between the predicted shape and the response signal.

10. A method according to claim 9, wherein the calculated difference is determined on an L1 norm criterion.

11. A method according to claim 9, wherein the calculated difference is determined on a least square criterion.

12. A method according to claim 8, wherein information about the signal transmitted through the materials and attenuation properties of said materials are used to predict the examination zone.

13. A method according to claim 2, wherein a liquid is provided between the point of transmission and the structure.

14. A method according to claim 13, wherein the liquid comprises water.

15. A method according to claim 1, wherein the structure comprises a pipe.

16. A method according to claim 15, wherein the pipe comprises a plurality of layers.

17. A method according to claim 2, wherein duration of the signal transmitted is less than the time required for said signal to cover a first distance, said first distance extending from the point of transmission to an interface between two materials, at least one said two materials being comprised in the structure.

18. A method according to claim 17, wherein the first distance extends between the point of transmission and the first layer.

19. A method according to claim 2, wherein the signal transmitted from the point of transmission is an ultrasonic signal.

20. A method according to claim 1, wherein an outer layer of the structure comprises the first layer.

21. An apparatus for determining thickness of a layer in a structure comprising at least one layer, the apparatus comprising:
means for transmitting a signal and means for detecting a response signal,
processing means adapted to process the response signal in accordance with the method of claim 1.

22. An apparatus according to claim 21, wherein the processing means comprises a computer programme adapted to perform the method according to claim 1.

23. A computer system comprising data processing means which co-operates with computer program means to perform the method of claim 1.

24. A computer programme for a computer system according to claim 23.

25. The use of the method according to claim 1, wherein the method is used to determine thickness of layers in a pipe during production of said pipe.
